(19) United States
(12) Patent Application Publication
(10) Pub. No.: US 2015/0243923 A1
(43) Pub. Date: Aug. 27, 2015

(54) Optoelectronic component and method for producing an optoelectronic component

(71) Applicant: OSRAM OPTO SEMICONDUCTORS GMBH, Regensburg (DE)

(72) Inventors: Thilo Reusch, Donaustauf (DE); Daniel Steffen Setz, Boeblingen (DE); Thomas Wehlus, Lappersdorf (DE)

(73) Assignee: OSRAM OLED GMBH, Regensburg (DE)

(21) Appl. No.: 14/431,781

(22) PCT Filed: Sep. 26, 2013
(86) PCT No.: PCT/EP2013/070065

§ 371 Date: Mar. 27, 2015

(30) Foreign Application Priority Data
Sep. 28, 2012 (DE) 10 2012 109 258.3

(51) Int. Cl. H01L 51/52

(52) U.S. Cl. CPC H01L 51/524; H01L 51/5268

(57) ABSTRACT

Various embodiments may relate to an optoelectronic component, including a glass substrate, a glass layer on the glass substrate, and encapsulation, which includes a glass fit, wherein the glass frit is arranged on the glass layer. The glass frit is fastened on the glass substrate by the glass layer. The glass layer is configured as an adhesion promoter for the glass frit on the glass substrate. The glass frit is configured in such a way that a laterally hermetically tight seal of the optoelectronic component is formed by the glass frit.

### RELATED APPLICATIONS

The present application is a national stage entry according to 35 U.S.C. §371 of PCT application No.: PCT/EP2013/070065 filed on Sep. 26, 2013, which claims priority from German application No.: 10 2012 109 258.3 filed on Sep. 28, 2012, and is incorporated herein by reference in its entirety.

### TECHNICAL FIELD

In various embodiments, an optoelectronic component and a method for producing an optoelectronic component are provided.

### BACKGROUND

An optoelectronic component (for example an organic light-emitting diode (OLED), for example a white organic light-emitting diode (WOLED), a solar cell, etc.) on an organic basis is conventionally distinguished by mechanical flexibility and moderate production conditions. Optoelectronic components on an organic basis, for example organic light-emitting diodes, are furthermore finding increasingly widespread use and can be used for the illumination of surfaces. A surface may for example be understood as a table, a wall or a floor.

In order to increase the proportion of electromagnetic radiation which can be output from an organic optoelectronic component, for example an organic light-emitting diode, or for example can be input in the case of an organic solar cell, the organic optoelectronic component is conventionally provided with a scattering layer.

To date, there are two approaches for increasing the light output: external output and internal output.

External output may be understood as devices in which light is output from the substrate in the emitted light. Such a device may, for example, be a film with scattering particles or surface structuring, for example microlenses. The film with scattering particles is, for example, applied onto the outer side of the substrate. The surface structuring may, for example, direct structuring of the outer side of the substrate or the introduction of scattering particles into the substrate, for example into the glass substrate. Some of these approaches, for example the scattering film, are already used in OLED illumination modules, or their ability to be scaled up has been demonstrated. External output may, however, have two essential disadvantages. The output efficiency in the case of external output may be limited to from approximately 60% to approximately 70% of the light guided in the substrate. Furthermore, in the case of external output measures, the appearance of the optoelectronic component may be substantially influenced. By the applied layers or films, for example, a surface which appears milky and/or is diffusely reflective may be formed on the optoelectronic component.

Internal output may be understood as devices in which light that is guided in the electrically active region of the optoelectronic component, for example the organic functional layer structure and/or the electrodes, for example the transparent electrically conductive oxide layers (transparent conductive oxide—TCO) is output. In other optoelectronic components, i.e. not for organic optoelectronic components, several technological approaches are known. In a conventional device for the internal output of light, a grating with a low refractive index may be applied on or over one of the electrodes of the optoelectronic component, for example an electrode made of indium tin oxide (ITO). The grating has structured regions including a material with a low refractive index. In another conventional device for the internal output of light, a scattering layer may be applied over an electrode, for example the indium tin oxide anode. The scattering layer conventionally includes a matrix consisting of a polymer, in which scattering centers are distributed. The matrix generally has a refractive index of approximately 1.5, and the scattering centers have a higher refractive index than the matrix. The substance mixture of matrix and scattering centers is conventionally applied wet-chemically.

Besides the output of light from the organic optoelectronic component, the encapsulation of the organic optoelectronic component is a further problem. The organic constituents of organic components, for example the organic functional layer structure of an organic light-emitting diode, are often susceptible to harmful environmental influences. A harmful environmental influence may be understood as all influences which may potentially lead to degradation or ageing and/or alteration of the structure of an organic substance or substance mixture, and therefore limit the operating life of organic components. For this reason, optoelectronic component are often encapsulated against harmful environmental influences.

One conventional method for the encapsulation of the electrically active region, for example the organic functional layer structure, of an optoelectronic component on or over a soda-lime substrate glass is encapsulation on the basis of a cover glass having a cavity (cavity glass), in which a so-called getter is introduced. The electrically active region is formed on or over a glass substrate. The cavity glass is adhesively bonded onto the glass substrate in such a way that the electrically active region is arranged in the cavity of the cavity glass. Owing to the special production process of the cavity glass, however, cavity glass is much more expensive than normal flat glass (soda-lime silicate glass).

Another conventional method for the encapsulation of an electrically active region, for example an organic functional layer structures of an optoelectronic component on or over a soda-lime substrate glass is thin-film encapsulation or thin-film encapsulation with lamination glass. By the application of suitable thin films, organic components can be sealed sufficiently against water and oxygen. A lamination glass for protecting the thin-film encapsulation from mechanical damage may be adhesively bonded onto the thin-film encapsulation. Extreme quality requirements may be placed on the thin-film encapsulation, and the deposition process of the many different layers of thin-film encapsulation may be very time-consuming.

In optoelectronic components, for example OLED displays, the encapsulation of the components may, for example, be carried out by glass frit encapsulation (glass frit bonding/glass soldering/seal glass bonding). In the case of glass frit encapsulation, a glass with a low melting point, which is also referred to as a glass frit, can be used as a connection between a glass substrate and a cover glass. A part of the optoelectronic component, for example the electrically active region, for example the organic functional layer structure, is formed between the glass substrate and the cover glass. Connection of the glass frit to the cover glass and the glass substrate can protect the organic functional layer structure laterally from harmful environmental influences in the region of the glass frit. For organic optoelectronic components, for example OLEDs for illumination, this type of encapsulation represents an interesting alternative. In the highly cost-driven sector of general illumination, however, other more economical substrates are used than, for example, in OLED displays. In organic optoelectronic components for illumination, economical glass substrates are often used, for example soda-lime silicate glass (soda-lime glass). On a soda-lime silicate glass, however, glass frit encapsulation has not to date been possible. One problem which arises is the incompatibility of the thermal expansion of the soda-lime silicate glass when the glass frit is heated at the solder position.

### SUMMARY

In various embodiments, an optoelectronic component and a method for producing an optoelectronic component are provided, with which it is possible to increase the input and/or output of electromagnetic radiation, for example light, into/out of one or more optoelectronic components, and additionally to permit glass frit encapsulation of organic optoelectronic components with a favorable glass substrate.

An optoelectronic component may be understood as a semiconductor component which can provide or receive electromagnetic radiation.

In the scope of this description, provision of electromagnetic radiation may be understood as emission of electromagnetic radiation.

In the scope of this description, reception of electromagnetic radiation may be understood as absorption of electromagnetic radiation.

An electromagnetic radiation-emitting/absorbing component may in various embodiments be an electromagnetic radiation-emitting/absorbing semiconductor component and/or be configured as an electromagnetic radiation-emitting/absorbing diode, as an organic electromagnetic radiation-emitting/absorbing diode, as an electromagnetic radiation-emitting transistor or as an organic electromagnetic radiation-emitting transistor. The radiation may for example be light in the visible range, UV light and/or infrared light. In this context, the electromagnetic radiation-emitting/absorbing component may, for example, be configured as a light-emitting diode (LED), as an organic light-emitting diode (OLED), as a light-emitting transistor or as an organic light-emitting transistor. The light-emitting/absorbing component may in various embodiments be part of an integrated circuit. Furthermore, a multiplicity of light-emitting components may be provided, for example fitted in a common package.

In the scope of this description, an organic substance may be understood as a compound of carbon existing in chemically uniform form and distinguished by characteristic physical and chemical properties, regardless of the respective aggregate state. Furthermore, in the scope of this description, an inorganic substance may be understood as a compound without carbon, or a simple carbon compound, existing in chemically uniform form and distinguished by characteristic physical and chemical properties, regardless of the respective aggregate state. In the scope of this description, an organic-inorganic substance (hybrid substance) may be understood as a compound including compound parts which contain carbon and compound parts which are free of carbon, existing in chemically uniform form and distinguished by characteristic physical and chemical properties, regardless of the respective aggregate state. In the scope of this description, the term “substance” includes all substances mentioned above, for example an organic substance, an inorganic substance and/or a hybrid substance. Furthermore, in the scope of this description, a substance mixture may be understood as something that consists of constituents of two or more different substances, the constituents of which are for example very finely distributed. A substance class is to be understood as a substance or a substance mixture consisting of one or more organic substances, one or more inorganic substances or one or more hybrid substances. The term “material” may be used synonymously with the term “substance”.

In the scope of this description, a luminescent substance may be understood as a substance which converts electromagnetic radiation of one wavelength into electromagnetic radiation of another wavelength, for example a longer wavelength (Stokes shift) or a shorter wavelength (anti-Stokes shift) with losses, for example by phosphorescence or fluorescence. The energy difference between absorbed electromagnetic radiation and emitted electromagnetic radiation may be converted into phonons, i.e. heat, and/or by emission of electromagnetic radiation with a wavelength as a function of the energy difference.

A shape-stable substance may become plastically deformable, i.e. become liquefied, by addition of plasticizers, for example solvents, or increasing the temperature.

A plastically deformable material may become shape-stable, i.e. become solidified, by a crosslinking reaction and/or extraction of plasticizers.

The solidification of a substance or substance mixture, i.e. the conversion of a substance from deformable to shape-stable, may include a change in the viscosity, for example an increase in the viscosity from a first viscosity value to a second viscosity value. The second viscosity value may be several times greater than the first viscosity value, for example in a range of from approximately 10 to approximately 10⁶. The substance may be deformable at the first viscosity and shape-stable at the second viscosity.

The solidification of a substance or substance mixture, i.e. the conversion of a substance from deformable to shape-stable, may include a method or a process in which low-molecular-weight constituents are removed from the substance or substance mixture, for example solvent molecules or uncrosslinked low-molecular-weight constituents of the substance or of the substance mixture, for example drying or chemical crosslinking of the substance or of the substance mixture. The substance or the substance mixture may have a higher concentration of low-molecular-weight substances in the overall substance or substance mixture in the deformable state than in the shape-stable state.

The connection of a first body to a second body may be with a form fit, force fit and/or material fit. The connections may be configured to be releasable, i.e. reversible. In various configurations, a reversible connection with a fit may, for example, be produced as a screw connection, hook and loop connection, clamping/use of clamps.

The connections may however also be configured to be non-releasable, i.e. irreversible. A non-releasable connection may in this case be separated only by breaking the connection means. In various configurations, an irreversible connection with a fit may for example be produced as a rivet connection, an adhesive bond or a soldered connection.

In the case of a material-fit connection, the first body may be connected to the second body by atomic and/or molecular forces. Material-fit connections may often be non-releasable connections. In various configurations, a material-fit connection may be produced for example as an adhesive bond, a soldered connection, for example of a glass solder, or of a metal solder, or a welded connection.

In the scope of this description, a harmful environmental influence may be understood as all influences which may potentially lead to degradation or ageing of organic substances or substance mixtures, and therefore limit the operating life of organic components.

A harmful environmental influence may for example be a substance which is harmful for organic substances or organic substance mixtures, for example oxygen, water and/or for example a solvent.

A harmful environmental influence may, however, also be for example an environment which is harmful for organic substances or organic substance mixtures, for example a change in the environmental parameters above or below a critical value. An environmental parameter may, for example, be the temperature and/or the ambient pressure. In this way, for example crosslinking, degradation and/or crystallization or the like, of the organic substance or substance mixture may take place.

In various embodiments, an optoelectronic component is provided, the optoelectronic component including: a glass substrate; a glass layer on the glass substrate; and encapsulation, which includes a glass frit, wherein the glass frit is arranged on the glass layer; wherein the glass frit is fastened on the glass substrate by the glass layer.

In one configuration, the encapsulation may include a cover glass, which is connected with a fit, for example with a material fit, to the glass layer by the glass frit.

The connection with a fit by the glass frit may be understood as lateral sealing of the encapsulated part of the optoelectronic component, for example of the electrically active region, against harmful environmental influences.

In one configuration, the cover glass may include or be formed from a similar substance or the same substance as the glass substrate.

In one configuration, a second glass layer may be applied on or over the cover glass, in which case the second glass layer may be configured similarly or identically to the glass layer on or over the glass substrate. For example, the second glass layer may be configured as a glass layer without scattering centers.

The second glass layer may be configured as an adhesion promoter for the glass frit on the cover glass.

In another configuration, a light output layer may be arranged on or over the glass layer, and/or the glass layer may be configured as a light output layer.

The light output layer may, for example, be configured similarly or identically to the glass layer. For example, the glass layer may not include scattering additives and the light output layer may include scattering additives. The glass layer may, however, for example, include other additives than the light output layer, and/or be configured as an adhesion promoter layer for the light output layer.

In one configuration, the glass substrate may include or be formed from a soft glass, for example a silicate glass, for example a soda-lime silicate glass.

In one configuration, the glass layer may be configured as an adhesion promoter for the glass frit on the glass substrate.

In other words: the glass layer may have stronger adhesion to the glass substrate and the glass frit than the glass frit to the glass substrate, for example approximately 10% greater, for example approximately 20% greater, for example approximately 30% greater, for example approximately 50% greater, for example approximately 100% greater, for example approximately 300% greater.

In one configuration, the thermal expansion coefficient of the glass layer may be adapted to the thermal expansion coefficient of the glass frit, or the thermal expansion coefficient of the glass frit may be adapted to the thermal expansion coefficient of the glass layer, for example within a range of approximately 50%, for example within a range of approximately 40%, for example within a range of approximately 30%, for example within a range of approximately 20%, for example within a range of approximately 10%, for example approximately equal, in terms of the thermal expansion coefficient of the glass frit or the thermal expansion coefficient of the glass layer.

In other words: the glass layer and the glass frit may have an approximately equal thermal expansion coefficient.

In one configuration, the softening point of the glass layer may be adapted to the softening point of the glass frit, or the softening point of the glass frit may be adapted to the softening point of the glass layer, for example within a range of approximately 50%, for example within a range of approximately 40%, for example within a range of approximately 30%, for example within a range of approximately 20%, for example within a range of approximately 10%, for example approximately equal, for example within a temperature range of less than approximately 100° C., for example within a temperature range of less than approximately 70° C., for example within a temperature range of less than approximately 50° C., for example within a temperature range of less than approximately 20° C., in terms of the softening point of the glass frit or the softening point of the glass layer.

In other words: the glass layer and the glass frit may have an approximately equal softening point.

In one configuration, the glass layer may be arranged on or over the entire surface of the glass substrate.

In another configuration, the glass layer may have an average refractive index greater than or approximately equal to the refractive index of further layers in the layer cross section.

In one configuration, the glass layer may have a refractive index of at least approximately 1.5, for example a refractive index of at least approximately 1.6, for example a refractive index of at least approximately 1.65, for example a range of from approximately 1.7 to approximately 2.5.

In another configuration, the glass layer may have a thickness in a range of from approximately 1 μm to approximately 100 μm, for example in a range of from approximately 10 μm to approximately 100 μm, for example approximately 25 μm.

In another configuration, the glass layer may be configured as a layer in a layer plane of an organic light-emitting diode and/or an organic solar cell.

In one configuration, the glass layer may include a matrix and additives distributed therein.

In another configuration, the matrix of the glass layer may have a refractive index greater than approximately 1.7.

In another configuration, the matrix of the glass layer may be configured to be amorphous.

In another configuration, the matrix of the glass layer may include or be formed from a substance or substance mixture from the group of glass systems: systems containing PbO: PbO—B₂O₃, PbO—SiO₂, PbO—B₂O₃—SiO₂, PbO—B₂O₃—ZnO₂, PbO—B₂O₃—Al₂O₃, in which case the glass solder containing PbO may also include Bi₂O₃; systems containing Bi₂O_{3:} Bi₂O₃—B₂O₃, Bi₂O₃—B₂O₃—SiO₂, Bi₂O₃—B₂O₃—ZnO, Bi₂O₃—B₂O₃—ZnO—SiO₂.

In another configuration, the glass layer including Bi may additionally include a substance or a substance mixture from the group of substances: Al₂O₃, alkaline earth metal oxides, alkali metal oxides, ZrO₂, TiO₂, HfO₂, Nb₂O₅, Ta₂O₅, TeO₂, WO₃, MO₃, Sb₂O₃, Ag₂O, SnO₂, rare earth oxides.

In one configuration, UV-absorbing additives may be added as glass components to the glass of the matrix. For example, substances or substance mixtures that include Ce compounds, Fe compounds, Sn compounds, Ti compounds, Pr compounds, Eu compounds and/or V compounds may be added as glass quantity constituents in the glass melt process to low-melting-point glasses, for example glasses containing lead, in order to increase the UV absorption.

A glass melt process may be understood as thermal liquefying, i.e. melting, of a glass. The UV-absorbing additives may be dissolved as a constituent in the glass. Following the glass melt process, the glass may be powdered, applied onto a carrier in the form of coatings, and subsequently vitrified by a heat treatment.

In another configuration, the substance or the substance mixture of the matrix may have an intrinsically lower UV transmission than the glass substrate.

By the lower UV transmission of the matrix, UV protection can be formed for layers on or over the glass layer. The lower UV transmission of the matrix of the glass layer relative to the glass substrate may, for example, be formed by higher absorption and/or reflection of UV radiation.

In another configuration, the substance or the substance mixture of the matrix of the glass layer may be liquefied at a temperature of up to at most approximately 600° C.

In another configuration, the matrix may include at least one type of additive.

In one configuration, the additives may include or be formed from an inorganic substance or an inorganic substance mixture.

In another configuration, the at least one type of additive may include or be formed from a substance or a substance mixture or a stoichiometric compound from the group of substances: TiO₂, CeO₂, Bi₂O₃, ZnO, SnO₂, Al₂O₃, SiO₂, Y₂O₃, ZrO₂, luminescent substances, colorants, and UV-absorbing glass particles, suitable UV-absorbing metal nanoparticles, in which case the luminescent substances may for example exhibit absorption of electromagnetic radiation in the UV range.

In another configuration, the additives may be formed as particles, i.e. particulate additives.

In another configuration, the additives may have a curved surface, for example similar or identical to an optical lens.

In another configuration, the particulate additives may have a geometrical shape and/or a part of a geometrical shape from the group of shapes: spherical, aspherical, for example prismatic, ellipsoid, hollow, compact, platelet or rod-shaped.

In one configuration, the particulate additives may include or be formed from glass.

In one configuration, the particulate additives may have an average particle size in a range of from approximately 0.1 μm to approximately 10 μm, for example in a range of from approximately 0.1 μm to approximately 1 μm.

In another configuration, the additives may include a layer with a thickness of from approximately 0.1 μm to approximately 100 μm on or over the glass substrate in the glass layer.

In another configuration, the additives of the glass layer may include a plurality of layers above one another on or over the glass substrate, in which case the individual layers may be configured differently.

In another configuration, the average size of the particulate additives of at least one particulate additive may decrease from the surface of the glass substrate in the layers of the additives.

In another configuration, the individual layers of the additives may have a different average size of the particulate additives and/or a different transmission for electromagnetic radiation in at least one wavelength range, for example with a wavelength less than approximately 400 nm.

In another configuration, the individual layers of the additives may have a different average size of the particulate additives and/or a different refractive index for electromagnetic radiation.

In one configuration, the glass layer may be configured as a scattering layer, i.e. as a light output layer or light input layer.

In one configuration, the glass layer may include particulate additives that are configured as scattering particles for electromagnetic radiation, for example light, in which case the scattering particles may be distributed in the matrix.

In other words: the matrix may include at least one type of scattering additives, so that the glass layer can additionally form a scattering effect in relation to incident electromagnetic radiation in the at least one wavelength range, for example by a different refractive index of the scattering particles or scattering additives than the matrix and/or a diameter which approximately corresponds to the size of the wavelength of the radiation to be scattered.

The scattering effect may relate to electromagnetic radiation that is emitted or absorbed by an organic functional layer system on or over the glass layer, for example in order to increase the light output or light input.

In another configuration, the glass layer with scattering additives may have a difference of the refractive index of the scattering additives from the refractive index of the matrix of greater than approximately 0.05.

In one configuration, an additive may be configured as a colorant.

In the scope of this description, a colorant may be understood as a chemical compound or a pigment that can color other substances or substance mixtures, i.e. modify the external appearance of the substance or the substance mixture. The term “color” may also be understood as “change in color” by a colorant, in which case the external color of a substance may be changed in color, without coloring the substance, i.e. the “change in color” of a substance may not always include “coloration” of the substance.

The following substance classes and derivatives of colorants may be suitable as organic colorants: acridine, acridone, anthraquinone, anthracene, cyanine, dansyl, squaryllium, spiropyranes, boron dipyrromethanes (BODIPY), perylene, pyrene, naphthalenes, flavins, pyrroles, porphrins and metal complexes thereof, diarylmethane, triarylmethane, nitro, nitroso, phthalocyanine and metal complexes thereof, quinones, azo, indophenol, oxazines, oxazones, thiazines, thiazoles, xanthenes, fluorenes, flurones, pyronines, rhodamines, coumarins, metallocenes.

In one configuration, the colorant may include or be formed from an inorganic substance from the group of inorganic colorant classes, inorganic colorant derivatives or inorganic colorant pigments: transition metals, rare earth oxides, sulfides, cyanides, iron oxides, zirconium silicates, bismuth vanadate, chromium oxides.

In one configuration, the colorant may include or be formed from nanoparticles, for example carbon, such as carbon black, gold, silver, platinum.

In one configuration, the optical appearance of the glass layer may be modified by the colorant.

In one configuration, the colorant may absorb electromagnetic radiation in an application-specifically nonrelevant wavelength range, for example greater than approximately 700 nm.

In this way, the optical appearance of the glass layer can be modified, for example the glass layer can be colored, without impairing the efficiency, in a range technically nonrelevant for the use of the optoelectronic component.

In one configuration, an additive of the glass layer may be configured as a type of UV-absorbing additive, the UV-absorbing additive reducing the transmission relative to the matrix and/or the glass substrate for electromagnetic radiation with a wavelength less than approximately 400 nm, in at least one wavelength range.

The lower UV transmission of the glass layer with a UV-absorbing additive relative to the glass substrate and/or the matrix may, for example, be formed by higher absorption and/or reflection and/or scattering of UV radiation by the UV-absorbing additive.

In one configuration, the type of UV-absorbing additive may include or be formed from a substance, a substance mixture or a stoichiometric compound from the group of substances: TiO₂, CeO₂, Bi₂O₃, ZnO, SnO₂, a luminescent substance, UV-absorbing glass particles and/or suitable UV-absorbing metal nanoparticles, in which case the luminescent substance, the glass particles and/or the nanoparticles exhibit absorption of electromagnetic radiation in the UV range.

The UV-absorbing nanoparticles may have no solubility or a low solubility in the molten glass solder and/or not react therewith, or react only poorly therewith. Furthermore, the nanoparticles may lead to no scattering, or only low scattering, of electromagnetic radiation, for example nanoparticles which have a particle size of less than approximately 50 nm, for example of TiO₂, CeO₂, ZnO or Bi₂O₃.

In one configuration, an additive of the glass layer may be configured as a wavelength-converting additive, for example as a luminescent substance.

The luminescent substance may have a Stokes shift and emit incident electromagnetic radiation with a longer wavelength, or have an anti-Stokes shift and emit incident electromagnetic radiation with a shorter wavelength.

In the scope of this description, a luminescent substance may for example include or be formed from Ce³⁻-doped garnets such as YAG:Ce and LuAG, for example (Y,Lu)₃(Al,Ga)₅O₁₂:Ce^{3|}; Eu^{2|}-doped nitrides, for example CaAlSiN₃:Eu²⁺, (Ba,Sr)₂Si₅N₈:Eu²⁺; Eu²⁺-doped sulfides, SIONs, SiAlON, orthosilicates, for example (Ba,Sr)₂SiO₄:Eu²⁺; chlorosilicates, chlorophosphates, BAM (barium magnesium aluminate:Eu) and/or SCAP, halophosphate.

In another configuration, the additives may scatter electromagnetic radiation, absorb UV radiation, convert the wavelength of electromagnetic radiation and/or color the glass layer.

Additives which, for example, can scatter electromagnetic radiation and cannot absorb UV radiation may, for example, include or be formed from Al₂O₃, SiO₂, Y₂O₃ or ZrO₂.

Additives which, for example, scatter electromagnetic radiation and convert the wavelength of electromagnetic radiation may, for example, be configured as glass particles with a luminescent substance.

In one configuration, the glass layer may be structured, for example topographically, for example laterally and/or vertically; for example by a different substance composition of the glass layer, for example laterally and/or vertically, for example with a different local concentration of at least one additive.

In one configuration, the concentration of the additives in the glass layer may be less or greater in the region of the glass frit than in the optically active region on or over the glass layer. The optically active region may, for example, correspond approximately to the electrically active region of the optoelectronic component.

In one configuration, the glass layer may be structured in the region of the connection of the glass layer to the glass frit.

In one configuration, the structuring of the glass layer in the region of the physical contact with the glass frit may be configured in order to increase the accuracy of the positioning of the glass frit on or over the glass layer, for example as an indentation.

In one configuration, the glass layer may have a structured interface.

The structured interface may, for example, be formed by roughening one of the interfaces or forming a pattern on one of the interface of the glass layer.

In one configuration, the structured interface of the glass layer may be formed by microlenses.

The microlenses and/or the interfacial roughness may for example be understood as scattering centers, for example for increasing the light input/light output.

In one configuration, the glass frit may include or be formed from a similar or identical substance as the glass layer on or over the glass substrate.

The substance or the substance mixture of the glass frit may, however, for example have a higher softening point and/or a higher thermal expansion than the glass substrate.

In one configuration, the glass frit may have a thickness in a range of from approximately 0.1 μm to approximately 100 μm, for example in a range of from approximately 1 μm to approximately 20 μm.

In various embodiments, a method for producing an optoelectronic component is provided, the method including: formation of a glass layer on or over a glass substrate; formation of encapsulation, wherein the formation of the encapsulation includes the application of at least one glass frit on or over a glass layer, wherein the glass frit is connected with a fit on the glass substrate by the glass layer.

In one configuration of the method, the at least one glass frit may be applied onto at least one region of the glass substrate.

In one configuration of the method, the formation of a connection with a fit may include melting and solidification of the glass frit, in such a way that the connection with a fit is formed as hermetically tight lateral encapsulation.

In one configuration of the method, the method may furthermore include: formation of layers of the optoelectronic component on or over the glass layer.

In one configuration of the method, the method may furthermore include: application of a cover glass on or over the at least one glass frit.

In one configuration of the method, the melted glass frit may connect the glass layer and the cover glass to one another with a fit.

The connection with a fit may be configured in such a way that the glass frit forms lateral sealing of the optoelectronic component against harmful environmental influences.

In one configuration of the method, the connection with a fit may be configured in such a way that hermetically tight encapsulation of the layers of the optoelectronic component is formed.

In other words: the cover glass, the glass frit and the glass substrate may hermetically seal, for example insulate, against harmful environmental influences the layers which are surrounded by the cover glass, the glass frit and the glass substrate.

In one configuration of the method, the cover glass may include or be formed from a similar or identical substance as the glass substrate.

In one configuration of the method, a second glass layer may be applied on or over the cover glass, in which case the second glass layer may be configured similarly or identically to the glass layer on or over the glass substrate.

The second glass layer may, for example, be configured as an adhesion promoter for the glass frit on the cover glass.

In another configuration of the method, a light output layer may be formed on or over the glass layer, and/or the glass layer may be configured as a light output layer.

The light output layer may, for example, be configured similarly or identically to the glass layer. For example, the glass layer may not include scattering additives and the light output layer may include scattering additives. The glass layer may, however, for example, include different additives to the light output layer and/or be configured as an adhesion promoter layer for the light output layer.

In one configuration of the method, the glass substrate may include or be formed from a soft glass, for example a silicate glass, for example a soda-lime silicate glass.

In one configuration of the method, the glass layer may include or be formed from a layer of a melted glass solder powder on or over the glass substrate, the melted glass layer having stronger adhesion to the glass substrate than the melted glass frit.

In one configuration of the method, the substance or the substance mixture of the glass solder powder of the glass layer may include or be formed from a substance or substance mixture from the group of glass systems: systems containing PbO: PbO—B₂O₃, PbO—SiO₂, PbO—B₂O₃—SiO₂, PbO—B₂O₃—ZnO₂, PbO—B₂O₃—Al₂O₃, in which case the glass solder containing PbO may also include Bi₂O₃; systems containing Bi₂O₃: Bi₂O₃—B₂O₃, Bi₂O₃—B₂O₃—SiO₂, Bi₂O₃—B₂O₃ZnO, Bi₂O₃—Bi₂O₃—ZnO—SiO₂.

In one configuration of the method, the thermal expansion coefficient of the glass layer may be adapted to the thermal expansion coefficient of the glass frit, for example by adapting the substance composition of the glass layer and/or of the glass frit, for example in the region of the physical contact of the glass frit with the glass layer.

For example, the glass layer may be formed laterally serially. In other words: the glass layer may be formed with a different substance composition in the edge regions of the glass substrate than the optically active region.

In one configuration of the method, the softening point of the glass layer may be adapted to the softening point of the glass frit, for example by adapting the substance composition of the glass layer and/or of the glass frit, for example in the region of the physical contact of the glass frit with the glass layer.

In one configuration of the method, the glass layer may be arranged on or over the entire surface of the glass substrate.

In another configuration of the method, the glass layer may have an average refractive index greater than or approximately equal to the refractive index of further layers in the layer cross section of the optoelectromagnetic component.

In one configuration of the method, the glass layer may have a refractive index of at least approximately 1.5, for example a refractive index of at least approximately 1.6, for example a refractive index of at least approximately 1.65, for example in a range of from approximately 1.7 to approximately 2.5.

In another configuration of the method, the glass layer may be configured with a thickness in a range of from approximately 1 μm to approximately 100 μm, for example in a range of from approximately 10 μm to approximately 100 μm, for example approximately 25 μm.

In another configuration of the method, the glass layer may be configured as a layer in a layer plane of an organic light-emitting diode or organic solar cell.

In another configuration of the method, the matrix of the glass layer may have a refractive index greater than approximately 1.7.

In another configuration of the method, the matrix of the glass layer may be configured to be amorphous.

In another configuration of the method, the matrix of the glass layer may include or be formed from a substance or substance mixture from the group of glass systems: systems containing PbO: PbO—B₂O₃, PbO—SiO₂, PbO—B₂O₃—SiO₂, PbO—B₂O₃—ZnO₂, PbO—B₂O₃—Al₂O₃, in which case the glass solder containing PbO may also include Bi₂O₃; systems containing Bi₂O₃: Bi₂O₃—B₂O₃, Bi₂O₃—B₂O₃—SiO₂, Bi₂O₃—B₂O₃—ZnO, Bi₂O₃—B₂O₃—ZnO—SiO₂.

In another configuration of the method, the glass layer including Bi may additionally include a substance or a substance mixture from the group of substances: Al₂O₃, alkaline earth metal oxides, alkali metal oxides, ZrO₂, TiO₂, HfO₂, Nb₂O₅, Ta₂O₅, TeO₂, WO₃, MO₃, Sb₂O₃, Ag₂O, SnO₂, rare earth oxides.

In one configuration of the method, UV-absorbing additives may be added as glass components to the glass of the matrix. For example, substances or substance mixtures that include Ce compounds, Fe compounds, Sn compounds, Ti compounds, Pr compounds, Eu compounds and/or V compounds may be added as glass quantity constituents in the glass melt process to low-melting-point glasses, for example glasses containing lead, in order to increase the UV absorption.

In another configuration of the method, the substance or the substance mixture of the matrix of the glass layer may have an intrinsically lower UV transmission than the glass substrate.

In another configuration of the method, the substance or the substance mixture of the matrix of the glass layer may be liquefied at a temperature of up to at most approximately 600° C.

In another configuration of the method, the matrix may include at least one type of additive.

In one configuration, the additives may include or be formed from an inorganic substance or an inorganic substance mixture.

In another configuration of the method, one type of additive may include or be formed from a substance or substance mixture or stoichiometric compound from the group of substances: TiO₂, CeO₂, Bi₂O₃, ZnO, SnO₂, Al₂O₃, SiO₂, Y₂O₃, ZrO₂, luminescent substances, colorants, and UV-absorbing glass particles, suitable UV-absorbing metal nanoparticles, in which case the luminescent substances may for example exhibit absorption of electromagnetic radiation in the UV range.

In another configuration of the method, the additives may be formed as particles, i.e. as particulate additives.

In another configuration of the method, the additives may have a curved surface.

In another configuration of the method, the geometrical shape of the scattering additives may have a geometrical shape and/or a part of a geometrical shape from the group of shapes: spherical, aspherical, for example prismatic, ellipsoid, hollow, compact, platelet or rod-shaped.

In one configuration of the method, the particulate additives may include or are formed from glass.

In one configuration of the method, the particulate additives may have an average particle size in a range of from approximately 0.1 μm to approximately 10 μm, for example in a range of from approximately 0.1 μm to approximately 1 μm.

In another configuration of the method, the additives may include a layer with a thickness of from approximately 5 nm to approximately 100 μm on or over the glass substrate in the glass layer.

In another configuration of the method, the additives of the glass layer may be applied as a plurality of layers above one another on or over the glass substrate, in which case the individual layers are configured differently.

In another configuration of the method, the layers of the additives may be configured in such a way that the average size of the particulate additives of at least one additive decrease from the surface of the glass substrate in the layers of the additives.

In another configuration of the method, the individual layers of the additives may have a different average size of the particulate additives and/or a different transmission for electromagnetic radiation in at least one wavelength range, for example with a wavelength less than approximately 400 nm.

In another configuration of the method, the individual layers of the additives may be configured with a different average size of the particulate additives and/or a different refractive index for electromagnetic radiation.

In one configuration of the method, the glass layer may furthermore be configured as a scattering layer.

In one configuration of the method, the additives may be configured as scattering particles, in which case the scattering particles may be distributed in the matrix.

In another configuration of the method, the glass layer with scattering additives may form a difference of the refractive index of the scattering additives from the refractive index of the matrix of greater than approximately 0.05.

In one configuration of the method, an additive may include a colorant or be configured as a colorant.

In one configuration of the method, the optical appearance of the glass layer may be modified by the colorant.

In one configuration of the method, the colorant may absorb electromagnetic radiation in an application-specifically nonrelevant wavelength range, for example greater than approximately 700 nm.

In one configuration of the method, an additive of the glass layer may be configured at least one type of UV-absorbing additive, the UV-absorbing additive reducing the transmission relative to the matrix and/or the glass substrate for electromagnetic radiation with a wavelength less than approximately 400 nm, in at least one wavelength range.

In one configuration of the method, the type of UV-absorbing additive may include or be formed from a substance, a substance mixture or a stoichiometric compound from the group of substances: TiO₂, CeO₂, Bi₂O₃, ZnO, SnO₂, a luminescent substance, UV-absorbing glass particles, and/or suitable UV-absorbing metal nanoparticles, in which case the luminescent substance, the glass particles and/or the nanoparticles are configured absorption of electromagnetic radiation in the UV range.

In one configuration of the method, a glass layer may be formed with a wavelength-converting additive, for example a luminescent substance.

In another configuration of the method, the additives may scatter electromagnetic radiation, absorb UV radiation and/or convert the wavelength of electromagnetic radiation.

In one configuration of the method, the particulate additives may be formed or applied in a layer on or over the glass substrate.

The glass solder powder of the substance or the substance mixture of the matrix may be applied on or over the layer of additives.

The glass solder powder may then be liquefied in such a way that a part of the liquefied glass solder flows between the particulate additives toward the surface of the glass substrate, in such a way that a part of the liquefied glass still remains above the added particulate additives.

The part of the glass layer above the particulate additives may have a thickness equal to or greater than the roughness of the top layer of the particulate additives without glass, so that at least a smooth surface is formed, i.e. the surface may have a low RMS (root mean square) roughness, for example less than 10 nm.

What is essential for this configuration of the method is the liquefying of the glass solder after the application of the additives. In this way, the distribution of the particulate additives in the glass layer can be adjusted, and a smooth surface of the glass layer can be formed in a single process of liquefying the glass solder of the substance or the substance mixture of the matrix of the glass layer, for example in a single heat-treatment process.

The production of a suspension or paste of glass solder particles of the substance or the substance mixture of the matrix, or with a glass solder powder of the substance or the substance mixture of the matrix, is in this sense not to be understood as liquefying, since the appearance of the glass particles is not altered by the suspension.

In another configuration of the method, in order to form the glass layer, the glass solder powder of the substance or the substance mixture of matrix may be mixed with additives and applied onto the glass substrate as a paste or suspension by screen or template printing. This can lead after vitrifying to a homogeneous distribution of the additives in the glass matrix.

Other methods for producing layers of suspensions or pastes may, for example, be doctor blading or spray methods.

In another configuration of the method, the suspension and/or the paste, which contains the glass solder of the substance or the substance mixture of the matrix and/or the particulate additives, may include liquid, volatile and/or organic constituents besides the glass solder of the substance or the substance mixture of the matrix and/or the particulate additives.

These constituents may for example be different additives, for example solvents, binders, for example cellulose, cellulose derivatives, nitrocellulose, cellulose acetate, acrylates, and may be added to the particulate additives or glass solder particles in order to adjust the viscosity for the respective method and for the respectively desired layer thickness.

Organic additives, which may usually be liquid and/or volatile, may be thermally removed from the glass solder layer, i.e. the layer can be thermally dried. Nonvolatile organic additives may be removed by pyrolysis. Increasing the temperature can accelerate or make possible the drying or pyrolysis.

In another configuration of the method, the glass solder particle suspension or glass solder particle paste of the substance or the substance mixture of the matrix and the suspension or paste in which the particulate additives are contained (for the case that they are different pastes or suspensions) may include miscible liquid, volatile and/or organic components. In this way, a phase separation or precipitation of additives within the dried suspension or paste in which the particulate additives are contained, or in the dried glass layer suspension or paste in which the particulate additives are contained, can be prevented.

In another configuration of the method, the glass solder particle suspension or glass solder particle paste of the substance or the substance mixture of the matrix, and/or of the paste in which the particulate additives are contained, may be dried by volatile constituents.

In another configuration of the method, the organic constituents (binders) may be removed essentially fully from the dried layer of the particulate additives and/or from the dried glass solder powder layer by raising the temperature.

In another configuration of the method, the glass solder or glass solder powder is softened in such a way that it can flow, for example become liquid, by raising the temperature to a second value, the second temperature being very much higher than the first temperature of the drying.

The maximum value of the second temperature for liquefying or vitrifying the glass powder layer of the matrix may depend on the specific glass substrate. The temperature regime (temperature and time) may be selected in such a way that the glass substrate does not deform, but the glass solder of the glass powder layer of the matrix already has a viscosity such that it can run, i.e. flow, smoothly and a very smooth vitreous surface can be formed.

The glass of the glass powder layer of the matrix may have a second temperature, i.e. the glass transition temperature, for example below the transformation point of the glass substrate, (viscosity of the glass substrate approximately η=10^{14.5} dPa·s) and at most at the softening temperature (viscosity of the glass substrate approximately η=10^{7.6} dPa·s) of the glass substrate, for example below the softening temperature and approximately at the upper cooling point (viscosity of the glass substrate approximately η=10^{13.0} dPa·s).

In another configuration of the method, the glass solder powder of the substance or the substance mixture of the matrix may be configured as a glass powder and be vitrified at a temperature of up to at most approximately 600° C., i.e. the glass solder powder of the substance or the substance mixture of the matrix softens in such a way that a smooth surface can form.

In other words: the glass solder powder of the substance or the substance mixture of the matrix of the glass layer may, when using a soda-lime silicate glass as the glass substrate, be vitrified at temperatures of up to at most approximately 600° C., for example at approximately 500° C.

The substance or the substance mixture of the glass substrate, for example a soda-lime silicate glass, should be thermally stable, i.e. have an unchanged layer cross section, at the glass transition temperature of the glass solder powder of the substance or the substance mixture of the matrix.

In another configuration of the method, at least one continuous glass connection without gaps of the glass substrate to the liquefied glass of the matrix above the particulate additives may be formed by liquefied glass between the particulate additives.

In another configuration of the method, the surface of the liquefied glass of the matrix above the particulate additives may additionally be smoothed once more after solidification by local heating.

In another configuration of the method, the local heating may be formed by plasma or laser radiation.

In another configuration, a glass solder film of the substance or the substance mixture of the matrix may be applied, for example placed or rolled, onto the glass substrate.

In one configuration, the applied glass solder film may be connected to the glass substrate with a fit.

In one configuration of the connection of the glass solder film to the glass substrate with a fit, the connection with a fit may be formed by laminating, for example by vitrifying, at temperatures of up to at most approximately 600° C.

In one configuration of the method, the glass layer may be structured, for example topographically, for example laterally and/or vertically; for example by a different composition of the glass layer, for example laterally and/or vertically, for example with a different local concentration of at least one additive.

In one configuration of the method, the concentration of the additives in the glass layer may be less or greater in the region of the glass frit than in the region of the optically active region, for example approximately that of the electrically active region, on or over the glass layer.

In one configuration of the method, the glass layer may be structured in the region of the connection with a fit.

In one configuration of the method, the structuring of the glass layer in the region of the physical contact with the glass frit may be configured for positioning the glass frit on or over the glass layer, for example as an indentation.

In one configuration of the method, the glass layer may have a structured interface.

In one configuration of the method, the structured interface of the glass layer may be formed as microlenses.

In one configuration of the method, the glass frit may include or be formed from a similar or identical substance as the glass layer on or over the glass substrate, for example similar or identical to the substance or substance mixture of the matrix of the glass layer.

In one configuration, the substance or the substance mixture of the glass frit may be applied onto or over the glass layer in a glass solder paste.

The glass solder paste of the glass frit may, for example, be configured similarly or identically to one of the configurations of the glass solder paste of the matrix.

In other words: the substance or the substance mixture of the glass frit may be deformable when the cover glass is applied onto the glass frit, so that the glass frit can form a form-fit connection with the cover glass.

In one configuration, the glass frit may be applied onto or over the glass layer as vitrified glass frit particles.

In one configuration of the method, the formation of connection of the cover glass to the glass layer with a fit by the glass frit may be formed by melting the glass frit.

In one configuration of the method, the substance or the substance mixture of the glass frit may be melted by bombardment with photons, for example until an increase in the temperature to approximately above the softening temperature of the glass frit.

In another configuration of the method, the substance or the substance mixture of the glass frit may be liquefied at a temperature of up to at most approximately 600° C.

Bombardment with photons may, for example, be formed as a laser with a wavelength in a range of from approximately 200 nm to approximately 1700 nm, for example a range of from approximately 700 nm to approximately 1700 nm, for example focused with a focal diameter in a range of from approximately 10 μm to approximately 2000 μm, for example pulsed, for example with a pulse duration in a range of from approximately 100 fs to approximately 0.5 ms, for example with a power of from approximately 50 mW to approximately 1000 mW, for example with a power density of from 100 kW/cm² to approximately 10 GW/cm², and for example with a repetition rate in a range of from approximately 100 Hz to approximately 1000 Hz.

In one configuration of the method, the glass frit may be formed with a thickness in a range of from approximately 0.1 μm to approximately 100 μm, for example in a range of from approximately 1 μm to approximately 20 μm.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a schematic cross-sectional view of an optoelectronic component, according to various embodiments;

FIG. 2 shows a schematic cross-sectional view of two encapsulations of an organic optoelectronic component;

FIG. 3 shows a schematic cross-sectional view of a further encapsulation of an organic optoelectronic component;

FIG. 4 shows a diagram of the method for producing an optoelectronic component, according to various embodiments; and

FIG. 5 shows a schematic cross-sectional view of an optoelectronic component, according to various embodiments.

### DETAILED DESCRIPTION

In the following detailed description, reference will be made to the appended drawings, which are part of this description and in which specific embodiments in which the invention may be implemented are shown for illustration. In this regard, direction terminology such as “up”, “down”, “forward”, “backward”, “front”, “rear”, etc. is used with reference to the orientation of the figure or figures being described. Since constituent parts of embodiments can be positioned in a number of different orientations, the direction terminology is used for illustration and is in no way restrictive. It is to be understood that other embodiments may be used and structural or logical modifications may be carried out, without departing from the protective scope of the present invention. It is to be understood that the features of the various embodiments described herein may be combined with one another, unless specifically indicated otherwise. The following detailed description is therefore not to be interpreted in a restrictive sense, and the protective scope of the present invention is defined by the appended claims.

In the scope of this description, terms such as “connected” or “coupled” are used to describe both direct and indirect connection, and direct or indirect coupling. In the figures, elements which are identical or similar are provided with identical references, insofar as this is expedient.

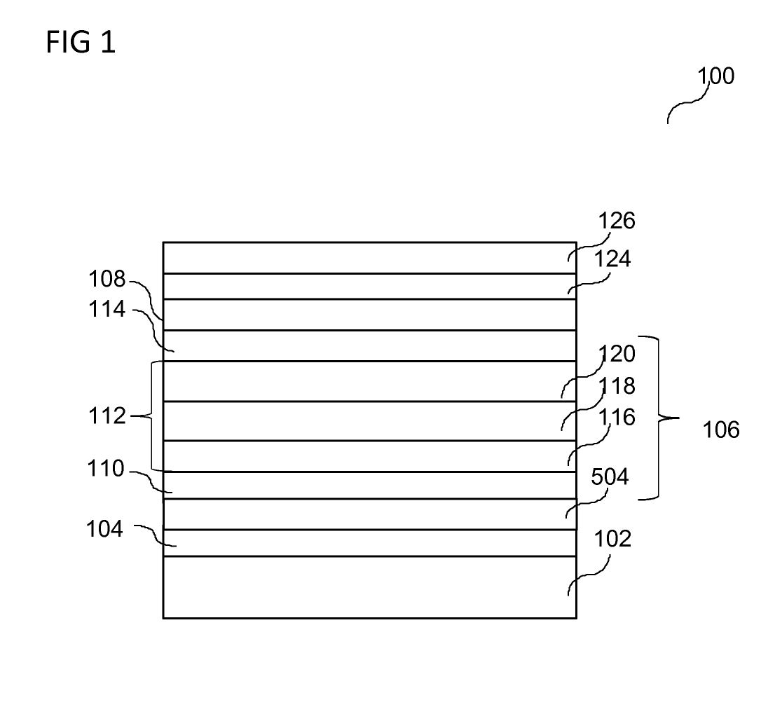

FIG. 1 shows a schematic cross-sectional view of an optoelectronic component, according to various embodiments.

Without restriction of generality, the optoelectronic component, according to various configurations, will be illustrated with reference to the example of an optoelectronic component providing electromagnetic radiation.

The represented configurations of the optoelectronic component may, however, also be used for an optoelectronic component receiving electromagnetic radiation.

The optoelectronic component 100, for example an organic electronic component 100 providing electromagnetic radiation, for example a light-emitting organic component 100, for example in the form of an organic light-emitting diode 100, may include a glass substrate 102.

The glass substrate 102 may for example be used as a carrier element for electronic elements or layers, for example light-emitting elements.

The glass substrate 102 may for example include or be formed from glass, for example a soft glass, for example a silicate glass, for example a soda-lime glass, or any other suitable substance.

The glass substrate 102 may be configured to be translucent or even transparent.

In various embodiments, the term “translucent” or “translucent layer” may be understood as meaning that a layer is transmissive for light, for example for the light generated by the light-emitting component, for example of one or more wavelength ranges, for example for light in a wavelength range of visible light (for example at least in a subrange of the wavelength range of from 380 nm to 780 nm). For example, in various embodiments, the term “translucent layer” is to be understood as meaning that essentially the total amount of light input into a structure (for example a layer) is also output from the structure (for example layer), in which case a part of the light may be scattered.

In various embodiments, the term “transparent” or “transparent layer” may be understood as meaning that a layer is transmissive for light (for example at least in a subrange of the wavelength range of from 380 nm to 780 nm), light input into a structure (for example a layer) also being output from the structure (for example layer) essentially without scattering or light conversion. In various embodiments, “transparent” is therefore to be regarded as a special case of “translucent”.

For the case in which, for example, a light-emitting electronic component which is monochromatic or limited in its emission spectrum is intended to be provided, it is sufficient for the optically translucent layer structure to be translucent at least in a subrange of the wavelength range of the desired monochromatic light, or for the limited emission spectrum.

In various embodiments, the organic light-emitting diode 100 (or the light-emitting components according to the embodiments described above or below) may be configured as a so-called top and bottom emitter. A top and/or bottom emitter may also be referred to as an optically transparent component, for example a transparent organic light-emitting diode.

In various embodiments, a barrier layer 104 may optionally be arranged on or over the glass substrate 102. The barrier layer 104 may include or consist of one or more of the following substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. Furthermore, in various embodiments, the barrier layer 104 may have a layer thickness in a range of from approximately 0.1 nm (one atomic layer) to approximately 5000 nm, for example a layer thickness in a range of from approximately 10 nm to approximately 200 nm, for example a layer thickness of approximately 40 nm.

According to various configurations, a glass layer 504 may be arranged on or over the barrier layer 104, or, if the barrier layer 104 is optional: on or over the glass substrate 102.

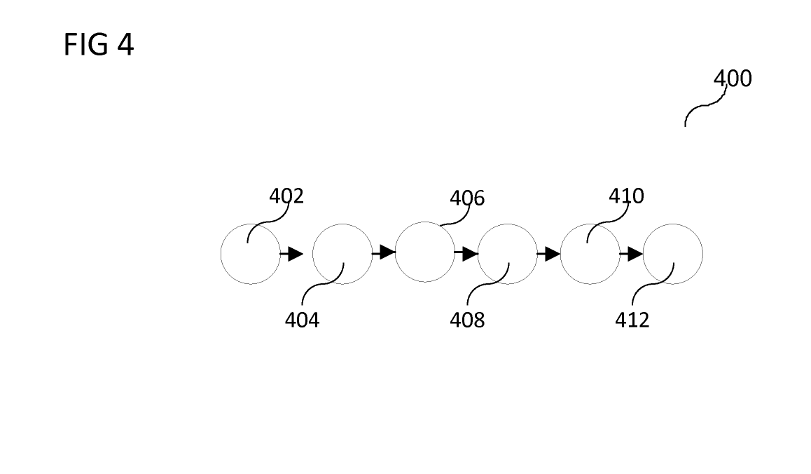

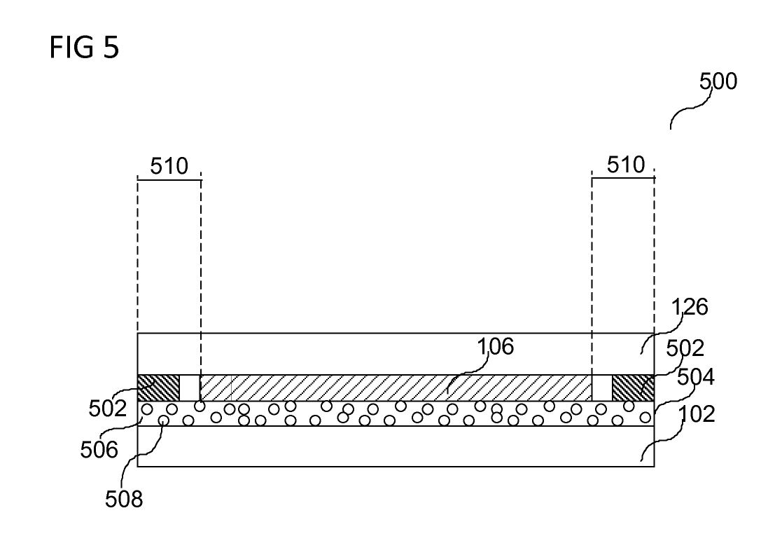

Further specifications of the glass layer 504 may be found from the description and/or the description of FIG. 4 and FIG. 5.

An electrically active region 106 of the light-emitting component 100 may be arranged on or over the glass layer 504. The electrically active region 106 may be understood as the region of the light-emitting component 100 in which an electric current flows in order to operate the light-emitting component 100.

In various embodiments, the electrically active region 106 may include a first electrode 110, a second electrode 114 and an organic functional layer structure 112, as will be explained in more detail below.

Thus, in various embodiments, the first electrode 110 (for example in the form of a first electrode layer 110) may be applied on or over the glass layer 504. The first electrode 110 (also referred to below as the lower electrode 110) may be formed from an electrically conductive substance, for example a metal or a transparent conductive oxide (TCO), or a layer stack of a plurality of layers of the same metal or different metals and/or of the same TCO or different TCOs. Transparent conductive oxides are transparent conductive substances, for example metal oxides, for example zinc oxide, tin oxide, cadmium oxide, titanium oxide, indium oxide or indium tin oxide (ITO). Besides binary metal-oxygen compounds, for example ZnO, SnO₂, or In₂O₃, ternary metal-oxygen compounds, for example AlZnO, Zn₂SnO₄, CdSnO₃, ZnSnO₃, MgIn₂O₄, GaInO₃, Zn₂In₂O₅ or In₄Sn₃O₁₂ or mixtures of various transparent conductive oxides also belong to the TCO group and may be used in various embodiments. Furthermore, the TCOs do not necessarily correspond to a stoichiometric composition, and may furthermore be p-doped or n-doped.

In various embodiments, the first electrode 110 may include a metal; for example Ag, Pt, Au, Mg, Al, Ba, In, Ca, Sm or Li, as well as compounds, combinations or alloys of these substances.

In various embodiments, the first electrode 110 may be formed from a layer stack of a combination of a layer of a metal on a layer of a TCO, or vice versa. One example is a silver layer, which is applied on an indium tin oxide layer (ITO) (Ag on ITO) or ITO/Ag/ITO multilayers.

In various embodiments, the first electrode 110 may include one or more of the following substances as an alternative or in addition to the substances mentioned above: networks of metal nanowires and nanoparticles, for example of Ag; networks of carbon nanotubes; graphene particles and graphene layers; networks of semiconducting nanowires.

Furthermore, the first electrode 110 may include electrically conductive polymers or transition metal oxides or transparent electrically conductive oxides.

In various embodiments, the first electrode 110 and the glass substrate 102 may be configured to be translucent or transparent. In the case that the first electrode 110 includes or is formed from a metal, the first electrode 110 may for example have a layer thickness less than or equal to approximately 25 nm, for example a layer thickness less than or equal to approximately 20 nm, for example a layer thickness less than or equal to approximately 18 nm. Furthermore, the first electrode 110 may for example have a layer thickness greater than or equal to approximately 10 nm, for example a layer thickness greater than or equal to approximately 15 nm. In various embodiments, the first electrode 110 may have a layer thickness in a range of from approximately 10 nm to approximately 25 nm, for example a layer thickness in a range of from approximately 10 nm to approximately 18 nm, for example a layer thickness in a range of from approximately 15 nm to approximately 18 nm.

Furthermore, for the case in which the first electrode 110 includes or is formed from a conductive transparent oxide (TCO), the first electrode 110 may for example have a layer thickness in a range of from approximately 50 nm to approximately 500 nm, for example a layer thickness in a range of from approximately 75 nm to approximately 250 nm, for example a layer thickness in a range of from approximately 100 nm to approximately 150 nm.

Furthermore, for the case in which the first electrode 110 are formed for example from a network of metal nanowires, for example of Ag, which may be combined with conductive polymers, a network of carbon nanotubes, which may be combined with conductive polymers, or of graphene layers and composites, the first electrode 110 may for example have a layer thickness in a range of from approximately 1 nm to approximately 500 nm, for example a layer thickness in a range of from approximately 10 nm to approximately 400 nm, for example a layer thickness in a range of from approximately 40 nm to approximately 250 nm.

The first electrode 110 may be configured as an anode, i.e. as a hole-injecting electrode, or as a cathode, i.e. as an electron-injecting electrode.

The first electrode 110 may include a first electrical contact pad, to which a first electrical potential (provided by an energy source (not represented), for example a current source or a voltage source) can be applied. As an alternative, the first electrical potential may be applied to the glass substrate 102 and then delivered indirectly via the latter to the first electrode 110. The first electrical potential may, for example, be the ground potential or another predetermined reference potential.

Furthermore, the electrically active region 106 of the light-emitting component 100 may include an organic functional layer structure 112, which is applied or formed on or over the first electrode 110.

The organic functional layer structure 112 may include one or more emitter layers 118, for example including fluorescent and/or phosphorescent emitters, as well as one or more hole conduction layers 116 (also referred to as hole transport layer or layers 120).

In various embodiments, as an alternative or in addition, one or more electron conduction layers 116 (also referred to as electron transport layer or layers 116) may be provided.

Examples of emitter materials which may be used in the light-emitting component 100 according to various embodiments for the emitter layer or layers 118 include organic or organometallic compounds, such as derivatives of polyfluorene, polythiophene and polyphenylene (for example 2- or 2,5-substituted poly-p-phenylene vinylene) and metal complexes, for example iridium complexes, for example blue phosphorescent FIrPic (bis(3,5-difluoro-2-(2-pyridyl)phenyl-(2-carboxypyridyl)-iridium III), green phosphorescent Ir(ppy)₃ (tris(2-phenylpyridine)iridium III), red phosphorescent Ru(dtb-bpy)₃*2(PF₆) (tris[4,4′-di-tert-butyl-(2,2′)-bipyridine]ruthenium(III) complex) and blue fluorescent DPAVBi (4,4-bis[4-(di-p-tolylamino)styryl]biphenyl), green fluorescent TTPA (9,10-bis[N,N-di-(p-tolyl)-amino]anthracene) and red fluorescent DCM2 (4-dicyanomethylene)-2-methyl-6-julolidyl-9-enyl-4H-pyrane) as nonpolymeric emitters. Such nonpolymeric emitters may, for example, be deposited by thermal evaporation. Furthermore, polymeric emitters may be used, which may in particular be deposited by a wet chemical method, for example spin coating method.

The emitter materials may be embedded in a suitable way in a matrix material.

It should be pointed out that other suitable emitter materials are likewise provided in other embodiments.

The emitter materials of the emitter layer or layers 118 of the light-emitting component 100 may, for example, be selected in such a way that the light-emitting component 100 emits white light. The emitter layer or layers 118 may include a plurality of emitter materials emitting different colors (for example blue and yellow or blue, green and red); as an alternative, the emitter layer or layers 118 may also be constructed from a plurality of sublayers, for example a blue fluorescent emitter layer 118 or blue phosphorescent emitter layer 118, a green phosphorescent emitter layer 118 and a red phosphorescent emitter layer 118. Mixing of the different colors can lead to the emission of light with a white color impression. As an alternative, a converter material may also be arranged in the beam path of the primary emission generated by these layers, which material at least partially absorbs the primary radiation and emits secondary radiation with a different wavelength, so that a white color impression is obtained from (not yet white) primary radiation by the combination of primary radiation and secondary radiation.

The organic functional layer structure 112 may in general include one or more electroluminescent layers. The one or more electroluminescent layers may include organic polymers, organic oligomers, organic monomers, nonpolymeric organic small molecules, or a combination of these substances. For example, the organic functional layer structure 112 may include one or more electroluminescent layers which is or are configured as a hole transport layer 120, so that, for example in the case of an OLED, effective hole injection into an electroluminescent layer or an electroluminescent region is made possible. As an alternative, in various embodiments, the organic functional layer structure 112 may include one or more functional layers which is or are configured as an electron transport layer 116, so that, for example in the case of an OLED, effective electron injection into an electroluminescent layer or an electroluminescent region is made possible. For example, tertiary amines, carbazole derivatives, conductive polyaniline or polyethylene dioxythiophene may be used as a substance for the hole transport layer 120. In various embodiments, the one or more electroluminescent layers may be configured as an electroluminescent layer.

In various embodiments, the hole transport layer 120 may be applied, for example deposited, on or over the first electrode 110, and the emitter layer 118 may be applied, for example deposited, on or over the hole transport layer 120. In various embodiments, an electron transport layer 116 may be applied, for example deposited, on or over the emitter layer 118.

In various embodiments, the organic functional layer structure 112 (i.e. for example the sum of the thicknesses of hole transport layer or layers 120 and emitter layer or layers 118 and electron transport layer or layers 116) may have a layer thickness of at most approximately 1.5 μm, for example a layer thickness of at most approximately 1.2 μm, for example a layer thickness of at most approximately 1 μm, for example a layer thickness of at most approximately 800 nm, for example a layer thickness of at most approximately 500 nm, for example a layer thickness of at most approximately 400 nm, for example a layer thickness of at most approximately 300 nm. In various embodiments, the organic functional layer structure 112 may for example include a stack of a plurality of organic light-emitting diodes (OLEDs) that are arranged directly above one another, in which case each OLED may for example have a layer thickness of at most approximately 1.5 μm, for example a layer thickness of at most approximately 1.2 μm, for example a layer thickness of at most approximately 1 μm, for example a layer thickness of at most approximately 800 nm, for example a layer thickness of at most approximately 500 nm, for example a layer thickness of at most approximately 400 nm, for example a layer thickness of at most approximately 300 nm. In various embodiments, the organic functional layer structure 112 may for example include a stack of two, three or four OLEDs that are arranged directly above one another, in which case, for example, the organic functional layer structure 112 may have a layer thickness of at most approximately 3 μm.

The light-emitting component 100 may in general optionally include further organic functional layers, for example arranged on or over the one or more emitter layers 118 or on or over the electron transport layer or layers 116, which are used to further improve the functionality and therefore the efficiency of the light-emitting component 100.

The second electrode 114 (for example in the form of a second electrode layer 114) may be applied on or over the organic functional layer structure 112, or optionally on or over the one or more further organic functional layer structures.

In various embodiments, the second electrode 114 may include or be formed from the same substances as the first electrode 110, metals being particularly suitable in various embodiments.

In various embodiments, the second electrode 114 (for example for the case of a metallic second electrode 114) may for example have a layer thickness less than or equal to approximately 50 nm, for example a layer thickness less than or equal to approximately 45 nm, for example a layer thickness less than or equal to approximately 40 nm, for example a layer thickness less than or equal to approximately 35 nm, for example a layer thickness less than or equal to approximately 30 nm, for example a layer thickness less than or equal to approximately 25 nm, for example a layer thickness less than or equal to approximately 20 nm, for example a layer thickness less than or equal to approximately 15 nm, for example a layer thickness less than or equal to approximately 10 nm.

The second electrode 114 may in general be configured in a similar way to the first electrode 110, or differently thereto. The second electrode 114 may, in various embodiments, be formed from one or more of the substances and with the respective layer thickness described above in connection with the first electrode 110. In various embodiments, the first electrode 110 and the second electrode 114 are both configured to be translucent or transparent. The light-emitting component 100 represented in FIG. 1 may therefore be configured as a top and bottom emitter (expressed in another way, as a transparent light-emitting component 100).

The second electrode 114 may be configured as an anode, i.e. as a hole-injecting electrode, or as a cathode, i.e. as an electron-injecting electrode.

The second electrode 114 may include a second electrical terminal, to which a second electrical potential (which is different to the first electrical potential) provided by the energy source can be applied. The second electrical potential may, for example, have a value such that the difference from the first electrical potential has a value in a range of from approximately 1.5 V to approximately 20 V, for example a value in a range of from approximately 2.5 V to approximately 15 V, for example a value in a range of from approximately 3 V to approximately 12 V.

Encapsulation 108, for example in the form of a barrier thin film/thin-film encapsulation 108, may optionally also be formed on or over the second electrode 114, and therefore on or over the electrically active region 106.

In the scope of this application, a “barrier thin film” 108 may, for example, be understood as a layer or a layer structure which is suitable for forming a barrier against chemical contaminants or atmospheric substances, in particular against water (moisture) and oxygen. In other words: the barrier thin film 108 is configured in such a way that it cannot be penetrated, or can be penetrated at most in very small amounts, by substances that damage OLEDs, such as water, oxygen or solvents.

According to one configuration, the barrier thin film 108 may be configured as an individual layer (expressed another way, as a single layer). According to an alternative configuration, the barrier thin film 108 may include a multiplicity of sublayers arranged on top of one another. In other words: according to one configuration, the barrier thin film 108 may be configured as a layer stack. The barrier thin film 108, or one or more sublayers of the barrier thin film 108, may for example be formed by a suitable deposition method, for example by an atomic layer deposition (ALD) method according to one configuration, for example a plasma-enhanced atomic layer deposition (PEALD) method or a plasma-less atomic layer deposition (PLALD) method, or by a chemical vapor deposition (CVD) method according to another configuration, for example a plasma-enhanced chemical vapor deposition (PECVD) method or a plasma-less chemical vapor deposition (PLCVD) method, or alternatively by other suitable deposition methods.

By using an atomic layer deposition (ALD) method, very thin layers can be deposited. In particular, layers whose layer thicknesses lie in the atomic layer range can be deposited.

According to one configuration, in the case of a barrier thin film 108 which includes a plurality of sublayers, all the sublayers may be formed by an atomic layer deposition method. A layer sequence which only includes ALD layers may also be referred to as a “nanolaminate”.

According to an alternative configuration, in the case of a barrier thin film 108 which includes a plurality of sublayers, one or more sublayers of the barrier thin film 108 may be deposited by a deposition method other than an atomic layer deposition method, for example by a chemical vapor deposition method.

The barrier thin film 108 may, according to one configuration, have a layer thickness of from approximately 0.1 nm (one atomic layer) to approximately 1000 nm, for example a layer thickness of from approximately 10 nm to approximately 100 nm according to one configuration, for example approximately 40 nm according to one configuration.

According to one configuration, in which the barrier thin film 108 includes a plurality of sublayers, all the sublayers may have the same layer thickness. According to another configuration, the individual sublayers of the barrier thin film 108 may have different layer thicknesses. In other words: at least one of the sublayers may have a different layer thickness than one or more of the other sublayers.

The barrier thin film 108, or the individual sublayers of the barrier thin film 108, may according to one configuration be configured as a translucent or transparent layer. In other words: the barrier thin film 108 (or the individual sublayers of the barrier thin film 108) may consist of a translucent or transparent substance (or a substance mixture which is translucent or transparent).

According to one configuration, the barrier thin film 108, or (in the case of a layer stack including a multiplicity of sublayers) one or more of the sublayers of the barrier thin film 108, may include or be formed from one of the following substances: aluminum oxide, zinc oxide, zirconium oxide, titanium oxide, hafnium oxide, tantalum oxide, lanthanum oxide, silicon oxide, silicon nitride, silicon oxynitride, indium tin oxide, indium zinc oxide, aluminum-doped zinc oxide, and mixtures and alloys thereof. In various embodiments, the barrier thin film 108, or (in the case of a layer stack including a multiplicity of sublayers) one or more of the sublayers of the barrier thin film 108, may include one or more high-index substances, or expressed another way one or more substances having a high refractive index, for example having a refractive index of at least 2.

In one configuration, the cover 126, for example made of glass, may be applied for example by frit bonding (glass frit bonding/glass soldering/seal glass bonding) by a glass solder in the geometrical edge regions of the organic optoelectronic component 100 with the barrier thin film 108.

In various embodiments, an adhesive and/or a protective coating 124 may be provided on or over the barrier thin film 108, by which, for example, a cover 126 (for example a glass cover 126) is fastened, for example adhesively bonded, on the barrier thin film 108. In various embodiments, the optically translucent layer of adhesive and/or protective coating 124 may have a layer thickness of more than 1 μm, for example a layer thickness of several μm. In various embodiments, the adhesive may include or be a lamination adhesive.

In various embodiments, light-scattering particulate additives, which can lead to a further improvement of the hue distortion and of the output efficiency, may also be embedded in the layer of adhesive (also referred to as the adhesive layer). In various embodiments, for example, dielectric scattering particulate additives may be provided as light-scattering particles, for example metal oxides, for example silicon oxide (SiO₂), zinc oxide (ZnO), zirconium oxide (ZrO₂), indium tin oxide (ITO) or indium zinc oxide (IZO), gallium oxide (Ga₂Oₐ) aluminum oxide or titanium oxide. Other particulate additives may also be suitable, so long as they have a refractive index which is different to the effective refractive index of the matrix of the translucent layer structure, for example air bubbles, acrylate, or hollow glass spheres. Furthermore, for example, metal nanoparticles, metals such as gold or silver, iron nanoparticles, or the like, may be provided as light-scattering particulate additives.

In various embodiments, an electrically insulating layer (not represented) may also be applied between the second electrode 114 and the layer of adhesive and/or protective coating 124, for example SiN, for example with a layer thickness in a range of from approximately 300 nm to approximately 1.5 μm, for example with a layer thickness in a range of from approximately 500 nm to approximately 1 μm, in order to protect electrically unstable substances, for example during a wet chemical process.

In various embodiments, the adhesive may be configured so that it itself has a refractive index which is less than the refractive index of the cover 126. Such an adhesive may for example be a low-index adhesive, for example an acrylate, which has a refractive index of approximately 1.3. Furthermore, a plurality of different adhesives, which form an adhesive layer sequence, may be provided.

Furthermore, it should be pointed out that, in various embodiments, an adhesive 124 may even be entirely omitted, for example in configurations in which the cover 126, for example consisting of glass, are applied for example by plasma spraying onto the barrier thin film 108.

In various embodiments, the cover 126 and/or the adhesive 124 may have a refractive index (for example at a wavelength of 633 nm) of 1.55.

Furthermore, in various embodiments one or more antireflection layers (for example combined with the encapsulation 108, for example the barrier thin film 108) may additionally be provided in the light-emitting component 100.

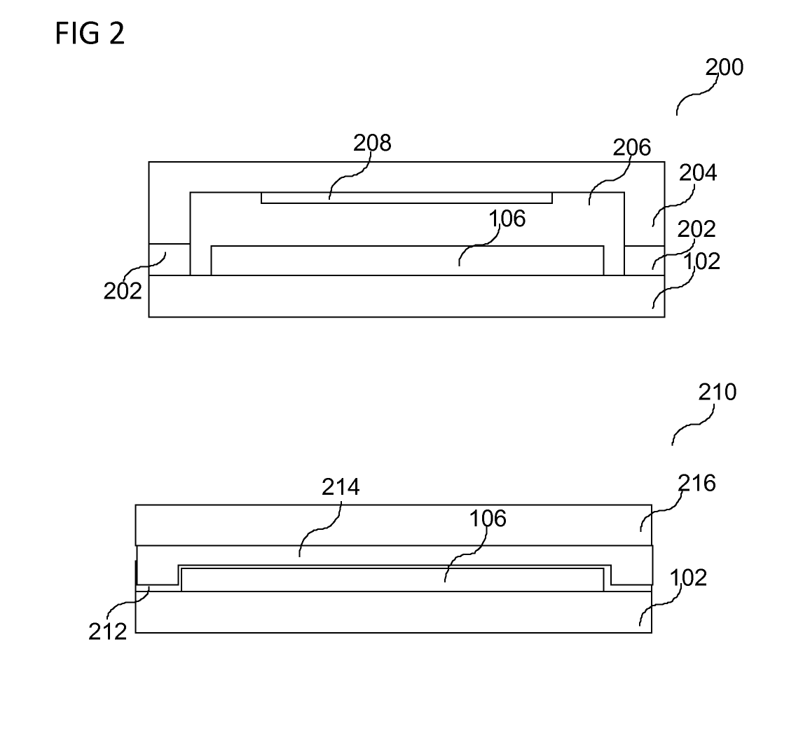

FIG. 2 shows a schematic cross-sectional view of two encapsulations of an organic optoelectronic component.

A method—represented in view 200—for encapsulating an electrically active region 106 of an optoelectronic component on or over a glass substrate 102, for example a soda-lime silicate glass 102, the encapsulation is based on a cover glass 204 having a cavity 206, in which a so-called getter 208 is introduced.

The getter 208 may be understood as an absorber 208 that can for example absorb harmful substances, for example water and/or oxygen.

The cavity 206 may for example be filled with an inert substance or substance mixture, for example an inert gas or an inert liquid.

The cavity glass 204 may, for example, be formed from a soda-lime silicate glass.

The cavity glass 204 is adhesively bonded onto the glass substrate 102 by an adhesive 202.

Owing to the special production process of the cavity glass 204, for example of the cavity 206 of the cavity glass 204, however, the cavity glass 204 is significantly more expensive than normal flat glass (soda-lime silicate glass).

A further method for encapsulating an electrically active region 106 of an optoelectronic component 100 on or over a soda-lime silicate glass 102 is represented in view 210.

A lamination glass 216 for protecting the thin-film encapsulation 212 from mechanical damage may be adhesively bonded onto the thin-film encapsulation 212 by a lamination adhesive 214.

The lamination glass 216 may, for example, be formed from a soda-lime silicate glass.

By the application of suitable thin films 212, organic components 100 can be sealed sufficiently against water and oxygen.

Extreme quality requirements may be placed on the thin-film encapsulation, and the deposition process of the many different layers of thin-film encapsulation may be very time-consuming.

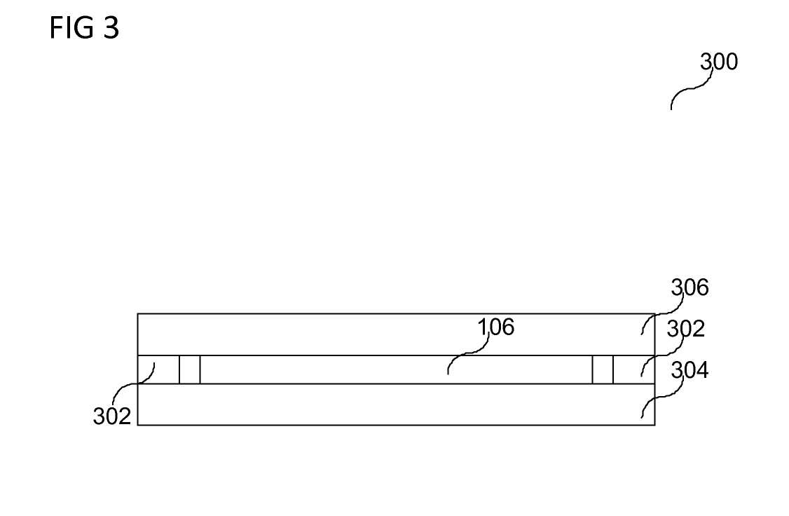

FIG. 3 shows a schematic cross-sectional view of a further encapsulation of an organic optoelectronic component.

In optoelectronic component 300, for example OLED displays 300, the encapsulation of the optoelectronic components may, for example, be carried out by a glass frit 302, i.e. glass frit encapsulation (glass frit bonding/glass soldering/seal glass bonding).

In the case of glass frit encapsulation, a glass 302 with a low melting point, which is also referred to as a glass frit 302, can be used as a connection between a glass substrate 304 and a cover glass.

A part of the optoelectronic component, for example the electrically active region 106, may be formed between the glass substrate 304 and the cover glass.

The connection of the glass frit 302 with the cover glass and the glass substrate 304 can protect the electrically active region 106 laterally from harmful environmental influences, for example water and/or oxygen entering, in the region of the glass frit 302.

For organic optoelectronic components 100, for example OLEDs, for illumination, this type of encapsulation represents an interesting alternative. In the highly cost-driven sector of general illumination with OLEDs, however, other glass substrates 102 are used than, for example, in OLED displays 300, for example display glass 304, for example an aluminum silicate glass 304.

In organic optoelectronic components for illumination 100, economical glass substrates 102 are often used, for example soda-lime silicate glass 102 (soda-lime glass).

On a soda-lime silicate glass 102, glass frit encapsulation has not to date been possible.

One problem which arises is the incompatibility of the thermal expansion of the soda-lime silicate glass of the glass substrate 102 when the glass frit 302 is heated at the solder position, for example during the vitrifying.

FIG. 4 shows a flowchart 400 of a method for producing an optoelectronic component, according to various embodiments.

The sequence of a method for producing an optoelectronic component, as represented for example in FIG. 5, is represented schematically.

The method (400) including: preparation 402 of a glass substrate 102, formation 404 of a glass layer 504, formation 406 of layers of an optoelectronic component, application 408 of a glass frit 502, application 410 of a cover glass 126, formation 412 of a connection with a fit between the glass layer 504, glass frit 502 and cover glass 126.

The preparation 402 of the glass substrate 102 (not represented), for example of a soda-lime silicate glass having a refractive index of approximately 1.5, may for example include the application of a barrier layer 104, for example an SiO₂ layer, cleaning of the surface of the glass substrate 102, or of the barrier layer 104; adjustment of the surface roughness or chemical groups on the surface 302 of the glass substrate 102, or of the barrier layer 104, for example as wet chemical cleaning, or be optional.

After the preparation 502 of the glass substrate 102, the method may include the formation 404 of a glass layer 504.

The formation 404 of the glass layer 504 may, for example, be formed by various methods.

Various configuration of a method for the formation 404 of the glass layer 504 will be presented below without restriction of generality.

In one configuration for the formation 404 of the glass layer 504, a glass layer precursor may be applied onto the glass substrate 102 by screen printing or template printing, for example with a glass solder powder suspension or glass solder powder paste, which may include a powder of bismuth borate glass particles or bismuth borosilicate glass particles, for example with a refractive index of greater than approximately 1.5, for example greater than approximately 1.6, for example greater than approximately 1.65, for example in a range of between approximately 1.7 and approximately 2.5.

The glass solder powder suspension or glass solder powder paste may include a commercially available screen-printing medium (for example nitrocellulose in ethyl acetate or cellulose derivatives in glycol ethers).

The bismuth borate glass particles or bismuth borosilicate glass particles may for example have a particle size distribution D50 of approximately 1 μm and a thermal expansion coefficient of approximately 8.5·10⁻⁶ 1/K for the temperature range of from approximately 50° C. to approximately 350° C.

As an alternative, for example, bismuth zinc borate glass particles or bismuth zinc borosilicate glass particles with a particle size distribution D50 of approximately 7 μm and a thermal expansion coefficient of approximately 10·10⁻⁶ 1/K for the temperature range of from approximately 50° C. to approximately 300° C. may also be selected.

After the application of the glass layer precursor, the glass layer precursor may be dried in order to remove volatile constituents, for example at 70° C. for 3 hours.

After the drying of the glass layer precursor, the nonvolatile organic constituents in the dried glass layer precursor may be thermally removed by removal of nonvolatile organic constituents, for example by pyrolysis.

The screen-printing medium should be selected in such a way that debinding is completed before the glass solder powder softens.

Since the bismuth borosilicate glass used may start to soften from approximately 500° C., the two binder/solvent systems mentioned above are highly suitable for this glass, as they can already burn out between approximately 200° C. and approximately 400° C., depending on the system.

After removal of the nonvolatile organic constituents, the glass layer precursor may be liquefied.

In the case of the aforementioned bismuth borosilicate glass as a glass powder layer, the vitrifying may take place at temperatures above approximately 500° C.

In the example of a soda-lime silicate glass as the glass substrate 102 with an upper cooling temperature of approximately 550° C., the upper temperature limit may have a value of approximately 600° C., depending on the heating method, in order to keep deformation of the glass substrate 102 small, or to avoid it.

During the vitrifying, the viscosity of the glass layer precursor, or of the glass solder particles, is reduced. In this way, the glass layer precursor, or the glass solder particles, can form a glass layer 504 on the surface of the glass substrate 102. This process is also referred to as vitrifying.

If the vitrifying takes place below the transformation temperature of the glass substrate 102, then no thermal stresses will be formed therein. The thermal expansion coefficient of the two bonding partners, i.e. the glass substrate 102 and the glass solder of the matrix of the glass layer, should not differ too greatly in order to avoid excessive bonding stresses between the glass substrate 102 and the protective layer 106, and thereby ensure a durable connection.

Since the glass layer 504 can act in a similar way to a barrier layer, a barrier thin film 104 can be obviated, for example when the substance or the substance mixture of the matrix 506 of the glass layer 504 does not contain alkali metals.

By the vitrifying, the thickness of the glass layer 504 can be reduced in relation to the thickness of the glass layer precursor by filling the intermediate spaces between the glass solder particles, for example to a thickness in a range of from approximately 1 μm to approximately 100 μm, for example in a range of from approximately 10 μm to and 50 μm, for example to approximately 25 μm.

After the liquefying of the glass layer precursor and the formation of the contour of the glass layer 504, the glass solder of the matrix 506 may be solidified, for example by cooling, for example passively cooled.

By the solidification of the glass of the matrix 506 of the glass layer 504, the glass layer 504 can be formed.

After the solidification of the glass layer 504, adjustment of the surface property of the glass layer 504 may be carried out, for example polishing, i.e. smoothing of the surface of the glass layer 504, for example by brief local raising of the temperature, for example by directed plasma, for example as fire polishing or also as laser polishing.

In one configuration of the glass layer 504, the glass layer 504 may include a glass matrix 506 and additives 508 distributed therein.

The formation 404 of a glass layer 504 with a matrix 506 and additives 508 may be carried out in different ways.

In one configuration of the method, the particulate additives may be formed or applied in a layer on or over the glass substrate 102. The glass solder powder of the substance or the substance mixture of the matrix approximately 506 may be applied on or over the layer of particulate additives 508. The glass solder powder may then be liquefied in such a way that a part of the liquefied glass solder flows between the particulate additives 508 toward the surface of the glass substrate, in such a way that a part of the liquefied glass still remains above the particulate additives 508.

The part of the glass layer 504 above the particulate additives 508 should have a thickness equal to or greater than the roughness of the top layer of the particulate additives 508 without glass, so that at least a smooth surface of the glass layer is formed, i.e. the surface has a low RMS (root mean square) roughness, for example less than 10 nm.

In one configuration, the roughness of the surface of the glass layer 504 may be configured or understood as scattering centers. By the roughness of the glass layer 504, for example, the proportion of the electromagnetic radiation output or input in the electrically active region 106 can be increased.

What is essential for this configuration of the method is the liquefying of the glass solder after the application of the particulate additives 508. In this way, the distribution of the particulate additives 508 in the glass layer 504 can be adjusted, and for example a smooth surface of the glass layer 504 can be formed in a single process of liquefying the glass solder of the substance or the substance mixture of the matrix 506 of the glass layer 504, for example in a single heat-treatment process.

The production of a suspension or paste of glass solder particles of the substance or the substance mixture of the matrix 506, or with a glass solder powder of the substance or the substance mixture of the matrix 506, is in this sense not to be understood as liquefying, since the appearance of the glass solder particles is not altered by the formation of the suspension.

In another configuration of the method, in order to form the glass layer 504, the glass solder powder of the substance or the substance mixture of the matrix 506 may be mixed with additives 508 and applied onto the glass substrate as a paste or suspension by screen or template printing. This can lead after vitrifying to a homogeneous distribution of the additives in the glass matrix. Other methods for producing layers of suspensions or pastes may, for example, be doctor blading or spray methods.

The additives may be formed differently, for example as particles or molecules, and/or have different effects or function, as will be explained below.

In one configuration, the additives may include or be formed from an inorganic substance or an inorganic substance mixture.

In another configuration, one type of additive may include or be formed from a substance or substance mixture or a stoichiometric compound from the group of substances: TiO₂, CeO₂, Bi₂O₃, ZnO, SnO₂, Al₂O₃, SiO₂, Y₂O₃, ZrO₂, luminescent substances, colorants, and UV-absorbing glass particles, suitable UV-absorbing metal nanoparticles, in which case the luminescent substances may for example exhibit absorption of electromagnetic radiation in the UV range.

In another configuration, the particulate additives may have a curved surface, for example similar to an optical lens.

In another configuration, the particulate additives may have a geometrical shape and/or a part of a geometrical shape from the group of shapes: spherical, aspherical, for example prismatic, ellipsoid, hollow, compact, platelet or rod-shaped.

In one configuration, the particulate additives may include or be formed from glass.

In one configuration, the particulate additives may have an average particle size in a range of from approximately 0.1 μm to approximately 10 μm, for example in a range of from approximately 0.1 μm to approximately 1 μm.

In another configuration, the additives may include a layer with a thickness of from approximately 0.1 μm to approximately 100 μm on or over the glass substrate in the glass layer.

In another configuration, the additives of the glass layer may include a plurality of layers above one another on or over the glass substrate, in which case the individual layers are configured differently.

In another configuration, the average size of the particulate additives of at least one particulate additive may decrease from the surface of the glass substrate in the layers of the additives.

In another configuration, the individual layers of the additives may have a different average size of the particulate additives and/or a different transmission for electromagnetic radiation in wavelength a wavelength range, for example with a wavelength less than approximately 400 nm.

In another configuration, the individual layers of the additives may have a different average size of the particulate additives and/or a different refractive index for electromagnetic radiation.

In one configuration, the glass layer may include particulate additives that are configured as scattering particles for electromagnetic radiation, in which case the scattering particles may be distributed in the matrix.

In other words: the matrix may include at least one type of scattering additives, so that the glass layer can additionally form a scattering effect in relation to incident electromagnetic radiation in at least one wavelength range, for example by a different refractive index than the matrix and/or a diameter which approximately corresponds to the size of the wavelength of the radiation to be scattered.

The scattering effect may relate to electromagnetic radiation that is emitted by an organic functional layer system on or over the protective layer, for example in order to increase the light output.

In another configuration, the glass layer with scattering additives may have a difference of the refractive index of the scattering additives from the refractive index of the matrix of greater than approximately 0.05.

In one configuration, an additive may be configured as a colorant.

In one configuration, the optical appearance of the glass layer may be modified by the colorant.

In one configuration, the colorant may absorb electromagnetic radiation in an application-specifically nonrelevant wavelength range, for example greater than approximately 700 nm.

In this way, the optical appearance of the glass layer can be modified, for example the glass layer can be colored, without impairing the efficiency of the optoelectronic component.

In one configuration, an additive of the glass layer may include at least one type of UV-absorbing additive, the UV-absorbing additive reducing the transmission relative to the matrix and/or the glass substrate for electromagnetic radiation with a wavelength less than approximately 400 nm, in at least one wavelength range.

The lower UV transmission of the glass layer with a UV-absorbing additive relative to the glass substrate and/or the matrix may, for example, be formed by higher absorption and/or reflection and/or scattering of UV radiation by the UV-absorbing additive.

In one configuration, the type of UV-absorbing additive may include or be formed from a substance, a substance mixture or a stoichiometric compound from the group of substances: TiO₂, CeO₂, Bi₂O₃, ZnO, SnO₂, a luminescent substance, UV-absorbing glass particles, and/or suitable UV-absorbing metal nanoparticles, in which case the luminescent substance, the glass particles and/or the nanoparticles exhibit absorption of electromagnetic radiation in the UV range.

The UV-absorbing nanoparticles may have no solubility or a low solubility in the molten glass solder and/or not react therewith, or react only poorly therewith. Furthermore, the nanoparticles may lead to no scattering, or only low scattering, of electromagnetic radiation, for example nanoparticles which have a particle size of less than approximately 50 nm, for example of TiO₂, CeO₂, ZnO or Bi₂O₃.

In one configuration, an additive of the glass layer may be configured as a wavelength-converting additive, for example a luminescent substance.

The luminescent substance may have a Stokes shift and emit incident electromagnetic radiation with a longer wavelength, or have an anti-Stokes shift and emit incident electromagnetic radiation with a shorter wavelength.

In another configuration, the additives may scatter electromagnetic radiation, absorb UV radiation and/or convert the wavelength of electromagnetic radiation.

Additives which, for example, can scatter electromagnetic radiation and cannot absorb UV radiation may, for example, include or be formed from Al₂O₃, SiO₂, Y₂O₃ or ZrO₂.

Additives which, for example, scatter electromagnetic radiation and convert the wavelength of electromagnetic radiation may, for example, be configured as glass particles with a luminescent substance.

In another configuration of the method, the suspension and/or the paste, which contains the glass solder of the substance or the substance mixture of the matrix and/or the particulate additives, may include liquid, volatile and/or organic constituents besides the glass solder of the substance or the substance mixture of the matrix and/or the particulate additives.

These constituents may be different additives, for example solvents, binders, for example cellulose, cellulose derivatives, nitrocellulose, cellulose acetate, acrylates, and may be added to the particulate additives or glass solder particles in order to adjust the viscosity for the respective method and for the respectively desired layer thickness.

Organic additives, which may usually be liquid and/or volatile, may be thermally removed from the glass solder layer, i.e. the layer can be thermally dried. Nonvolatile organic additives may be removed by pyrolysis. Increasing the temperature can accelerate or make possible the drying or pyrolysis.

In another configuration of the method, the glass solder particle suspension or glass solder particle paste of the substance or the substance mixture of the matrix and the suspension or paste in which the particulate additives are contained (for the case that they are different pastes or suspensions) may include miscible liquid, volatile and/or organic components. In this way, a phase separation or precipitation of additives within the dried suspension or paste in which the particulate additives are contained, or in the dried glass layer suspension or paste in which the particulate additives are contained, can be prevented.

In another configuration of the method, the glass solder particle suspension or glass solder particle paste of the substance or the substance mixture of the matrix, and/or of the paste in which the particulate additives are contained, may be dried by volatile constituents.

In another configuration of the method, the organic constituents (binders) may be removed essentially fully from the dried layer of the particulate additives and/or from the dried glass solder powder layer by raising the temperature.

In another configuration of the method, the glass solder or glass solder powder is softened in such a way that it can flow, for example become liquid, by raising the temperature to a second value, the second temperature being very much higher than the first temperature of the drying.

The maximum value of the second temperature for liquefying or vitrifying the glass powder layer of the matrix may depend on the glass substrate. The temperature regime (temperature and time) may be selected in such a way that the glass substrate does not deform, but the glass solder of the glass powder layer of the matrix already has a viscosity such that it can run, i.e. flow, smoothly and a very smooth vitreous surface can be formed.

The glass of the glass powder layer of the matrix may have a second temperature, i.e. the glass transition temperature, for example below the transformation point of the glass substrate (viscosity of the glass substrate approximately η=10^{14.5} dPa·s) and at most at the softening temperature (viscosity of the glass substrate approximately η=10^{7.6} dPa·s) of the glass substrates, for example below the softening temperature and approximately at the upper cooling point (viscosity of the glass substrate approximately η=10^{13.0} dPa·s).

In another configuration of the method, the glass solder powder of the substance or the substance mixture of the matrix may be configured as a glass powder and be vitrified at a temperature of up to at most approximately 600° C., i.e. the glass solder powder of the substance or the substance mixture of the matrix softens in such a way that a smooth surface can form.

In other words: the glass solder powder of the substance or the substance mixture of the matrix of the glass layer may, when using a soda-lime silicate glass as the glass substrate, be vitrified at temperatures of up to at most approximately 600° C., for example at approximately 500° C.

The substance or the substance mixture of the glass substrate, for example a soda-lime silicate glass, should be thermally stable, i.e. have an unchanged layer cross section, at the glass transition temperature of the glass solder powder of the substance or the substance mixture of the matrix.

In another configuration of the method, at least one continuous glass connection without gaps of the glass substrate to the liquefied glass of the matrix above the particulate additives may be formed by liquefied glass between the particulate additives.

In another configuration of the method, the surface of the liquefied glass of the matrix above the particulate additives may additionally be smoothed once more after solidification by local heating.

In another configuration of the method, the local heating may be formed by plasma or laser radiation.

In one configuration for the formation 404 of the glass layer 504, a glass solder film of the substance or the substance mixture of the glass layer 504 may be applied, for example placed or rolled, onto the glass substrate 102.

In one configuration, the glass solder film may be configured similarly or identically in substance to the glass solder paste of the above-explained configuration of the method for the formation of the glass layer 504.

In one configuration, the applied glass solder film may be connected to the glass substrate with a fit.

In one configuration of the connection of the glass solder film to the glass substrate with a fit, the connection with a fit may be formed by lamination, for example by vitrifying, of the glass solder film to the glass substrate at temperatures of up to at most approximately 600° C.

The electrically active region 106 may be formed on or over the glass layer 504, for example according to a configuration of the description of FIG. 1.

The formation 406 of the electrically active region 106 may for example be configured by deposition methods, for example by lithographic processes.

After the formation 406 of the electrically active region 106, one or more glass frits 502 may be applied or formed on or over the glass layer 504 in the geometrical edge region 510 of the glass substrate 102.

Before the application 408 of the at least one glass frit 502 onto the glass layer 504, the glass layer 504 may be exposed in the edge region 510 of the glass substrate 502.

In other words: before the application 408 of the at least one glass frit 502, the electrically active region 106 may be removed from the glass layer 504 in the edge region 510, or not be formed in the edge region 510.

In one configuration, the geometrical edge region 510 may be structured, for example include an indentation, for example in which the glass frit can be at least partially applied, in order to increase the accuracy of the positioning of the glass frit 502 on or over the glass layer 504.

The glass frit 502 may be configured similarly or identically to the substance or the substance mixture of the matrix 506 of the glass layer 504.

In one configuration, the glass frit 502 may be configured as a glass solder paste similar or identical to the glass solder paste of the substance or the substance mixture of the matrix 506 of the glass layer 504.

In one configuration, the glass frit 502 may be configured as a vitrified glass solder similar or identical to the vitrified glass solder of the substance or the substance mixture of the matrix 506 of the glass layer 504.

The glass frit 502 may, for example, be applied onto the glass layer 502 in such a way that the electrically active region 106 is surrounded, for example framed or enclosed, by the glass frit 502 on the glass layer 504.

The glass frit 502 may have an approximately greater height than the electrically active region, for example in a range of from approximately 1 μm to approximately 50 μm.

The width of the glass frit 502 may be any desired width, since hermetically tight lateral encapsulation of the electrically active region 106 can already be produced by a continuous connection of the cover glass 126 and the glass layer 502 with a fit by the glass frit 502.

The substance or the substance mixture of the glass frit 502 may, however, for example have a higher softening point and/or a higher thermal expansion than the glass substrate 102.

After the application 408 of the glass frit 502, a cover glass 126 may be applied onto or over the electrically active region 106 and the glass frit 502.

The cover glass 126 may for example include or be formed from a soft glass, for example a silicate glass, for example a soda-lime silicate glass.

A second glass layer (not represented) may, for example, be applied on or over the soda-lime silicate glass 126 as an adhesion promoter for the connection to the glass frit 502. The second glass layer may, for example, be configured and/or formed similarly or identically to the glass layer 504 on or over the glass substrate 102.

The space between the cover glass 126, the glass frit 502, the glass layer 504 and the electrically active region 106 may, for example, be filled with an inert substance or substance mixture, for example a getter material, a silicone, an epoxide, a silazane, an adhesive or the like.

The application 410 of the cover glass 126 may, for example, be carried out by placement of the cover glass 126 or rolling of the cover glass film 126.

The formation 412 of a connection between the cover glass 126, the glass frit 502 and the glass layer 504 with a fit may be carried out by heating the glass frit 502 above the softening temperature of the substance or the substance mixture of the glass frit 502.

In one configuration of the method, the substance or the substance mixture of the glass frit 502 may be melted, i.e. liquefied, by bombardment with photons, in such a way that an increase in the temperature to approximately above the softening temperature of the glass frit 502 is achieved.

In another configuration of the method, the substance or the substance mixture of the glass frit may be liquefied at a temperature of up to at most approximately 600° C.

Bombardment with photons may, for example, be formed as a laser with a wavelength in a range of from approximately 200 nm to approximately 1700 nm, for example a range of from approximately 700 nm to approximately 1700 nm, for example focused with a focal diameter in a range of from approximately 10 μm to approximately 2000 μm, for example pulsed, for example with a pulse duration in a range of from approximately 100 fs to approximately 0.5 ms, for example with a power of from approximately 50 mW to approximately 1000 mW, for example with a power density of from 100 kW/cm² to approximately 10 GW/cm², and for example with a repetition rate in a range of from approximately 100 Hz to approximately 1000 Hz.

FIG. 5 shows a schematic cross-sectional view of an optoelectronic component, according to various embodiments.

The encapsulation of an optoelectronic component 100 according to various embodiments is represented in the schematic cross-sectional view 500.

A glass substrate 102 is represented, on or over which a glass layer 504 is applied, for example is formed.

The formation of the glass layer 504 may, for example, be configured similarly or identically to one of the methods of the descriptions of FIG. 4.

An electrically active region 106 of an optoelectronic component 100, for example according to the descriptions of FIG. 1, may be formed or configured on or over the glass layer 504.

The glass layer 504 may be exposed in the geometrical edge regions 510. In other words: the electrically active region 106 may not wet the glass layer 504 in the geometrical edge regions 510 of the optoelectronic component.

A glass frit 502 may be applied and/or formed on or over these exposed regions 510 of the glass layer 504.

The glass frit 502 may, for example, be configured similarly or identically to one of the configurations of the descriptions of FIG. 4.

A cover glass 126 may be applied on or over the glass frit 502 and the electrically active region 106.

According to one of the configurations of the descriptions of FIG. 4, the glass frit 502 may connection the cover glass 126 to the glass layer 504 with a fit.

The cover glass 126, the glass frit 502 and the glass layer 504 on or over the glass substrate 102 may form a hermetically tight cavity in relation to harmful environmental influences for the electrically active region 106.

The glass frit 504 may, according to various configurations, include a matrix 506 in which additives 508 are distributed. The additives 508 may, for example, increase the output of electromagnetic radiation from the electrically active region 106.

The glass substrate 102 and the cover glass 126 may for example include an economical glass, for example a soft glass, for example a silicate glass, for example a soda-lime silicate glass.

In various embodiments, an optoelectronic component and a method for producing an optoelectronic component are provided, with which it is possible to increase the input and/or output of electromagnetic radiation, for example light, into/out of one or more organic optoelectronic components, and additionally to make possible the glass frit encapsulation of organic optoelectronic components with a favorable glass substrate.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An optoelectronic component, comprising:
a glass substrate;
a glass layer on the glass substrate; and
encapsulation, which comprises a glass frit, wherein the glass frit is arranged on the glass layer;
wherein the glass frit is fastened on the glass substrate by the glass layer, and
wherein the glass layer is configured as an adhesion promoter for the glass frit on the glass substrate; and
wherein the glass frit is configured in such a way that a laterally hermetically tight seal of the optoelectronic component is formed by the glass frit.

2. The optoelectronic component as claimed in claim 1,
wherein the thermal expansion coefficient of the glass layer is adapted to the thermal expansion coefficient of the glass frit.

3. The optoelectronic component as claimed in claim 1,
wherein the softening point of the glass layer is adapted to the softening point of the glass frit.

4. The optoelectronic component as claimed in claim 1,
wherein the glass layer is furthermore configured as a scattering layer.

5. The optoelectronic component as claimed in claim 4,
wherein the glass layer comprises scattering particles.

6. The optoelectronic component as claimed in claim 4,
wherein the glass layer is structured.

7. The optoelectronic component as claimed in claim 1,
wherein the glass layer is arranged over the entire surface of the glass substrate.

8. The optoelectronic component as claimed in claim 1,
wherein the glass layer has a layer thickness in a range of from approximately 10 μm to approximately 100 μm.

9. The optoelectronic component as claimed in claim 1,
wherein the glass layer has a refractive index of at least approximately 1.5.

10. The optoelectronic component as claimed in claim 1,
wherein the glass substrate comprises or is formed from a soft glass.

11. The optoelectronic component as claimed in claim 1,
wherein the encapsulation comprises a cover glass, which is connected with a fit to the glass layer by the glass frit.

12. A method for producing an optoelectronic component, the method comprising:
forming a glass layer on or over a glass substrate; and
forming encapsulation, wherein the forming the encapsulation comprises the application of at least one glass frit on or over a glass layer, wherein the glass frit (502) is connected with a fit on the glass substrate by the glass layer;
wherein the glass layer is configured as an adhesion promoter for the glass frit on the glass substrate; and
wherein the glass frit is configured in such a way that a laterally hermetically tight seal of the optoelectronic component is formed by the glass frit.

13. The method as claimed in claim 12,
wherein the formation of a connection with a fit comprises melting and solidification of the glass frit, in such a way that the connection with a fit is formed as hermetically tight lateral encapsulation.

14. The method as claimed in claim 13,
wherein the substance or the substance mixture of the glass frit is melted by bombardment with photons.

15. The optoelectronic component as claimed in claim 1,
wherein the glass layer has a refractive index of at least approximately 1.6.

16. The optoelectronic component as claimed in claim 1,
wherein the glass layer has a refractive index of at least approximately 1.65.

17. The optoelectronic component as claimed in claim 1,
wherein the glass substrate comprises or is formed from a silicate glass.

18. The optoelectronic component as claimed in claim 1,
wherein the glass substrate comprises or is formed from a soda-lime silicate glass.

19. The method as claimed in claim 13,
wherein the substance or the substance mixture of the glass frit is melted by laser.
